(19) United States
(12) Patent Application Publication
(10) Pub. No.: US 2026/0206538 A1
(43) Pub. Date: Jul. 16, 2026

(54) BONDING APPARATUS AND ARTICLE MANUFACTURING METHOD

(71) Applicant: CANON KABUSHIKI KAISHA, Tokyo (JP)

(72) Inventors: Kiyotaka NAKAMURA, Tochigi (JP); Yusuke KUBOTA, Shiga (JP)

(21) Appl. No.: 19/424,258

(22) Filed: Dec. 18, 2025

(30) Foreign Application Priority Data
Jan. 16, 2025 (JP) 2025-006262

(51) Int. Cl. H10P 72/50; H10P 72/00

(52) U.S. Cl. CPC H10P 72/53; H10P 72/0428

(57) ABSTRACT

The present disclosure provides a bonding apparatus for bonding a second member to each of a plurality of regions on a target bonding surface of a first member, comprising: a first holder configured to hold the first member in a state in which the target bonding surface faces down; and a second holder configured to hold the second member, wherein in a supply process of supplying the second member to the second holder, the second holder is arranged outside a space below the first member held by the first holder, and wherein in a bonding process of bonding, to one of the plurality of regions, the second member supplied to the second holder, the second holder is arranged inside the space.

### BACKGROUND

### Field of the Technology

The present disclosure relates to a bonding apparatus and an article manufacturing method.

### Description of the Related Art

Japanese Patent Laid-Open No. 2023-77928 discloses a bonding apparatus that bonds a die to each of a plurality of bonding target portions on a wafer held by a wafer stage.

If foreign particles adhere to (accumulate on) a target bonding surface of a wafer (first member), a bonding apparatus that bonds a die (second member) to each of a plurality of regions on the target bonding surface of the wafer bonds the die to the wafer via the foreign particles. In this case, the bonding strength and/or bonding accuracy between the wafer and the die may be insufficient.

### SUMMARY

The present disclosure provides a technique advantageous in reducing adhesion of foreign particles to a target bonding surface of a first member in a bonding apparatus that bonds a second member to each of a plurality of regions on the target bonding surface of the first member.

According to one aspect of the present disclosure, there is provided a bonding apparatus for bonding a second member to each of a plurality of regions on a target bonding surface of a first member, comprising: a first holder configured to hold the first member in a state in which the target bonding surface faces down; and a second holder configured to hold the second member, wherein in a supply process of supplying the second member to the second holder, the second holder is arranged outside a space below the first member held by the first holder, and wherein in a bonding process of bonding, to one of the plurality of regions, the second member supplied to the second holder, the second holder is arranged inside the space.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a schematic view showing an example of the configuration of a bonding apparatus according to the first embodiment;

FIG. 2 is a schematic view showing an example of the configuration of a stage;

FIG. 3 is a flowchart illustrating the operation procedure of the bonding apparatus according to the first embodiment;

FIGS. 4A to 4D are views for explaining the operation of the bonding apparatus according to the first embodiment;

FIG. 5 is a schematic view showing an example of the configuration of a die;

FIG. 6 is a schematic view showing an example of the configuration of a bonding apparatus according to the second embodiment;

FIG. 7 is a view showing an example of the arrangement of a receiving member in a wafer chuck; and

FIGS. 8A and 8B are views for explaining driving of the receiving member in the bonding apparatus according to the second embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which directions parallel to the surface (target bonding surface) of a first member are defined as the X-Y plane. Directions parallel to the X-axis, the Y-axis, and the Z-axis of the XYZ coordinate system are defined as the X direction, the Y direction, and the Z direction, respectively. A rotation about the X-axis, a rotation about the Y-axis, and a rotation about the Z-axis are defined as θX, θY, and θZ, respectively. Control and driving (movement) concerning the X-axis, the Y-axis, and the Z-axis mean control or driving (movement) concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively.

In embodiments to be described later, an example in which a wafer (substrate) on which semiconductor devices are formed is used as a first member, and a die (chip) obtained by dividing, into pieces, a wafer on which semiconductor devices are formed is used as a second member will be explained. A plurality of bonding regions to each of which the die as the second member is bonded are provided on the target bonding surface of the wafer as the first member. In this example, the first member and the second member are not limited to the wafer and the die, respectively, and various changes and modifications can be made within the scope of the present disclosure. Examples of the first member are a silicon wafer, a silicon wafer on which wirings are formed, a glass wafer, a glass panel on which wirings are formed, an organic panel (PCB) on which wirings are formed, and a metal panel, in addition to a wafer on which semiconductor devices are formed. The first member may be a wafer to which one or more dies are already bonded. Furthermore, examples of the second member are a stack of dies, a small piece of a material, an optical element, a MEMS, and a structure, in addition to a die obtained by dividing, into pieces, a wafer on which semiconductor devices are formed.

In the embodiments to be described later, various temporary or permanent bonding methods can be applied as a bonding method for the first member and the second member. Examples of the bonding method are bonding using an adhesive, temporary bonding using a temporary adhesive, bonding by hybrid bonding, atomic diffusion bonding, vacuum bonding, and bump bonding.

Industrial application examples of the embodiments to be described later will be explained next.

The first application example is manufacturing of a stacked memory. In a case where a bonding apparatus according to the embodiment to be described later is applied to manufacturing of a stacked memory, a wafer (substrate) on which a memory serving as a semiconductor device is formed is used as the first member, and a die (chip) on which a memory is formed is used as the second member. For example, in manufacturing of a stacked memory having eight memory layers, the die (second member) formed as the eighth memory layer is bonded on the wafer (first member) already having seven memory layers. Note that the final layer of the stacked memory may be not a memory layer but a layer on which a driver for driving the memory is formed.

The second application example is heterogeneous integration of a processor. The mainstream of conventional processors is a System On Chip (SoC) in which a logic circuit, a Random Access Memory (SRAM), and the like are formed in one semiconductor element. To the contrary, in heterogeneous integration, a plurality of types of elements are formed from separate wafers by applying a process optimal for each element, and bonded to manufacture a processor. This can implement cost reduction and yield improvement of processors. In a case where the bonding apparatus according to the embodiment to be described later is applied to heterogeneous integration, a wafer (substrate) on which a logic device serving as a semiconductor device is formed is used as the first member. A die (chip) separated after probing, such as an SRAM, an antenna, or a driver, is used as the second member. In heterogeneous integration, for example, dies (second members) of different types are sequentially bonded, so bonded objects to the wafer (first member) sequentially increase. More specifically, when a die having an SRAM is bonded onto a logic wafer, the logic wafer is the first member and the die having the SRAM is the second member. When a die having an element to be formed on the SRAM is bonded onto the die having the SRAM, a die having a logic wafer and an SRAM is the first member, and the die having the element is the second member. Note that when bonding a plurality of dies to overlap each other, as for the order of bonding, bonding is desirably started from a thin die such that a bonding head does not interfere with a bonded die.

The third application example is 2.5D bonding using a silicon interposer. The silicon interposer is a silicon wafer on which wirings are formed. The 2.5D bonding is a method of bonding a plurality of types of dies onto the silicon interposer, and electrically connecting the plurality of types of dies by the wirings on the silicon interposer. In a case where the bonding apparatus according to the embodiment to be described later is applied to the 2.5D bonding, a silicon wafer on which wirings are formed is used as the first member, and a separated die is used as the second member. In the 2.5D bonding, for example, a plurality of types of dies are bonded to the silicon interposer, so the structure of a silicon interposer to which one or more dies are already bonded is sometimes handled as the first member. Note that when bonding a plurality of types of dies onto a silicon interposer, as for the order of bonding, bonding is desirably started from a thin die such that a bonding head does not interfere with a bonded die.

The fourth application example is 2.1D bonding using an organic interposer or a glass interposer. The organic interposer is an organic panel (a PCB substrate or a CCL substrate) used as a package substrate, on which wirings are formed. The glass interposer is a glass panel on which wirings are formed. The 2.1D bonding is a method of bonding a plurality of types of dies to the organic interposer or the glass interposer, and electrically connecting the plurality of types of dies by the wirings on the interposer. In a case where the bonding apparatus according to the embodiment to be described later is applied to the 2.1D bonding, in 2.1D bonding using the organic interposer, an organic panel on which wirings are formed is used as the first member, and a separated die is used as the second member. To the contrary, in 2.1D bonding using the glass interposer, a glass panel on which wirings are formed is used as the first member, and a separated die is used as the second member. In the 2.1D bonding, for example, a plurality of types of dies are bonded to the organic interposer or the glass interposer, so the structure of an organic interposer or a glass interposer to which one or more dies are already bonded is sometimes handled as the first member. Note that when bonding a plurality of types of dies to an interposer, as for the order of bonding, bonding is desirably started from a thin die such that a bonding head does not interfere with a bonded die.

The fifth application example is temporary bonding in a fan-out package manufacturing process. Examples of a fan-out package as an advanced package applied to a semiconductor manufacturing process are a fan-out wafer-level package and a fan-out panel-level package. The fan-out wafer-level package is formed by reconstructing and packaging separated dies into a wafer shape using a mold resin. The fan-out panel-level package is formed by reconstructing and packaging separated dies into a panel shape using a mold resin. In such fan-out package, in packaging, rewirings from the dies to bumps are formed, or rewirings that bond different types of dies are formed on a molded reconstructed substrate. At this time, if the die array accuracy is low, when transferring the rewiring pattern using a step-and-repeat exposure apparatus, it can be difficult to accurately align the rewiring pattern to the dies. For this reason, in the fan-out package, it is required to accurately array the plurality of dies. In a case where the bonding apparatus according to the embodiment to be described later is applied to the fan-out package manufacturing process, a metal panel is used as the first member, and a separated die is used as the second member. More specifically, the plurality of separated dies are sequentially, temporarily bonded to the metal panel by a temporary adhesive using the bonding apparatus. After that, the plurality of dies that have temporarily been bonded to the metal panel are molded into a wafer shape or a panel shape by a molding apparatus, and peeled from the metal panel after molding. Thus, a reconstructed wafer or a reconstructed panel on which the plurality of dies are arrayed is manufactured. Note that in the fan-out package manufacturing process, the array of the plurality of dies may change in the molding process. Therefore, when temporarily bonding the plurality of dies onto the metal panel using the bonding apparatus, the bonding position of each die on the metal panel is desirably adjusted to correct the change of the array caused by the molding process.

The sixth application example is heterogeneous substrate bonding. For example, in an infrared image sensor, InGaAs known as a high-sensitivity material is used for a sensor unit configured to receive light, and silicon capable of implementing a high-speed process is used for a logic circuit configured to extract data. Accordingly, a high-sensitivity high-speed infrared image sensor can be manufactured. However, from InGaAs crystal, only wafers whose diameter is as small as 4 inches are mass-produced, which is smaller than a mainstream 300-mm silicon wafer. Hence, there has been proposed a method of bonding, to a 300-mm silicon wafer on which a logic circuit is formed, a die obtained by dividing an InGaAs substrate into pieces. The bonding apparatus according to the embodiment to be described later can also be applied to heterogeneous substrate bonding of bonding substrates made of different materials and having different sizes. In the application of the bonding apparatus to heterogeneous substrate bonding, a substrate with a large diameter such as a silicon wafer is used as the first member, and a die (small piece) of a material such as InGaAs is used as the second member. Note that the die (small piece) of the material such as InGaAs may be a slice of a crystal and is desirably cut into a rectangular shape.

### First Embodiment

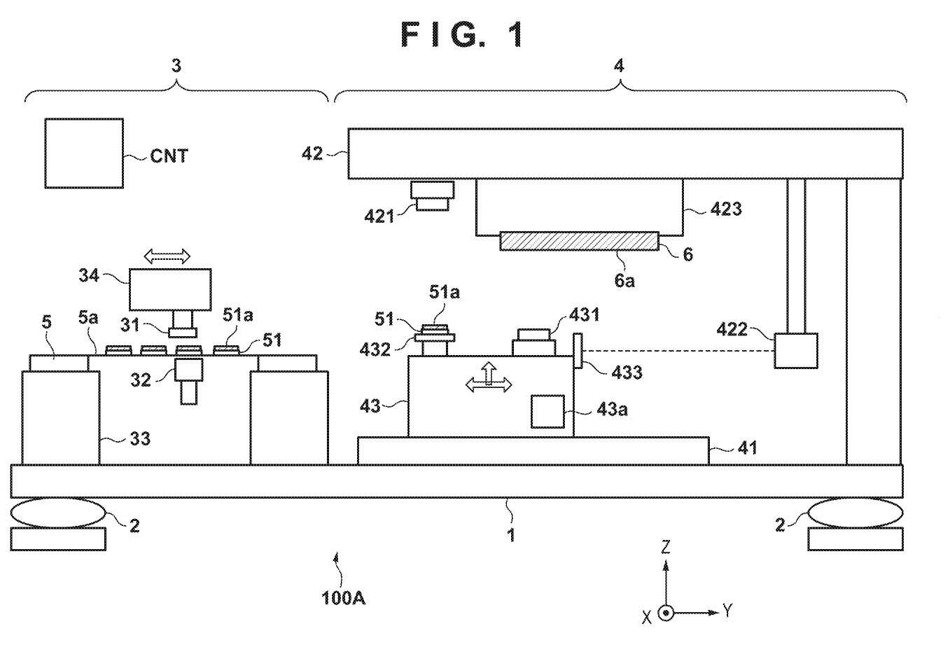

The first embodiment according to the present disclosure will be described. FIG. 1 is a schematic view showing an example of the configuration of a bonding apparatus 100A according to the first embodiment. In FIG. 1, a direction vertical to a target bonding surface 6a (lower surface) of a wafer 6 held by a wafer chuck 423 is defined as the Z direction, and directions orthogonal to each other in a plane parallel to the target bonding surface 6a of the wafer 6 are defined as the X direction and the Y direction. The bonding apparatus 100A is an apparatus that sequentially bonds a die 51 as a separated second member to each of a plurality of bonding regions on the target bonding surface 6a of the wafer 6 (substrate) as a first member. The plurality of dies 51 are arranged on a sheet 5a adhered to a dicing frame 5.

As shown in FIG. 1, the bonding apparatus 100A according to this embodiment includes a pickup unit 3, a bonding unit 4, and a controller CNT. The pickup unit 3 and the bonding unit 4 are mounted on a base 1 damped by mounts 2. The pickup unit 3 and the bonding unit 4 are mounted on the same base 1 in this embodiment, but may be individually mounted on separate bases.

The pickup unit 3 includes a pickup head 31, a release head 32, and a frame holder 33, and picks up the dies 51 one by one from the sheet 5a (for example, a dicing tape) adhered to the dicing frame 5. The frame holder 33 holds the dicing frame 5. The release head 32 pushes up the target die 51 from the back side of the sheet 5a adhered to the dicing frame 5 such that the target die 51 to be picked up projects upward from the remaining dies. At this time, the target die 51 is partially peeled from the dicing tape.

The pickup head 31 (supply head) picks up one die 51 from the sheet 5a on which the plurality of dies 51 are arranged and supplies it to a bonding head 432 to be described later. More specifically, the pickup head 31 holds (sucks), by a vacuum suction force or the like, the target die 51 pushed up by the release head 32, and picks up (separates) the target die 51 from the sheet 5a. The pickup head 31 is driven by a driving mechanism 34 to move from the pickup unit 3 to the bonding unit 4, and supplies (delivers) the die 51 to the bonding head 432 of the bonding unit 4.

In this embodiment, a target bonding surface 51a of each die 51 on the sheet 5a adhered to the dicing frame 5 faces up, and the pickup head 31 contacts the target bonding surface 51a of the die 51. Hence, when applying a bonding method of performing bonding by activating the surface, like hybrid bonding, highly stable coating such as diamond-like carbon (DLC) coating or fluorine coating is preferably performed on the target bonding surface 51a of each die 51.

The bonding unit 4 includes a lower base 41 and an upper base 42, and a stage 43 is mounted on the lower base 41. The bonding head 432 and a wafer observation camera 431 are provided on the stage 43. The stage 43 is configured to be movable in the X and Y directions and the θZ direction on the lower base 41, and is driven by a driving mechanism 43a including an actuator such as a linear motor. The driving mechanism 43a may have a function of driving the bonding head 432 in the Z direction and the θZ direction.

The bonding head 432 (second holder) holds, by a vacuum suction force or the like, the die 51 supplied from the pickup head 31. The bonding head 432 is driven in the Z direction by the driving mechanism 43a in a bonding process of bonding the die 51 to the target bonding surface 6a of the wafer 6 held by the wafer chuck 423 to be described later.

The wafer observation camera 431 (first camera) is arranged on the side of the bonding head 432 in the +Y direction (first direction), and captures the target bonding surface 6a of the wafer 6 held by the wafer chuck 423 to be described later. The wafer observation camera 431 is used to obtain (measure) the surface state and/or the position of a pattern in a target region to which the die 51 on the bonding head 432 is bonded among the plurality of bonding regions on the target bonding surface 6a of the wafer 6. For example, using a known image processing technique, the controller CNT detects the position of a feature point of the pattern in the target region from an image obtained by capturing the target region on the target bonding surface 6a of the wafer 6 by the wafer observation camera 431. Thus, the controller CNT can measure the position of the target region on the wafer 6 in the X and Y directions and/or the θZ direction. Note that the wafer observation camera 431 may be a camera that can capture patterns or marks formed on the back surface (the surface opposite to the target bonding surface 6a) of the wafer 6 and/or in the wafer 6, by using infrared light.

The stage 43 also includes a mirror 433 for measuring the position of the stage 43. The mirror 433 serves as the target of an interferometer 422 that measures the position of the stage 43. The interferometer 422 is fixed to the upper base 42, irradiates the mirror 433 provided on the stage 43 with light, and measures the position of the stage 43 based on reflected light from the mirror 433. The controller CNT can control the position of the stage 43 (bonding head 432 and wafer observation camera 431) in the X and Y directions and the θZ direction based on the position of the stage 43 measured by the interferometer 422.

Mechanisms mounted on the upper base 42 (fixing member) will be described next. The wafer chuck 423 and a die observation camera 421 are provided on the upper base 42. In this embodiment, the wafer chuck 423 and the die observation camera 421 are fixed to the lower surface of the upper base 42.

The wafer chuck 423 (first holder) holds the wafer 6 by a vacuum suction force or the like in a state in which the target bonding surface 6a of the wafer 6 faces down (that is, in the -Z direction). In the bonding apparatus 100A according to this embodiment, when the wafer chuck 423 holds the wafer 6 in a state in which the target bonding surface 6a of the wafer 6 faces down, it is possible to reduce the occurrence of a bonding failure caused by adhesion (accumulation) of foreign particles to the target bonding surface 6a of the wafer 6. Although the wafer chuck 423 of this embodiment is fixed to the upper base 42, the wafer chuck 423 may be configured to be movable in the Z direction and/or the θZ direction.

The bonding process of this embodiment is performed by driving the bonding head 432 in the Z direction, but may be performed by relatively driving the bonding head 432 and the wafer chuck 423 in the Z direction. The wafer 6 and the die 51 are aligned by driving the bonding head 432 in the X and Y directions and the θZ direction in this embodiment, but may be aligned by relatively driving the bonding head 432 and the wafer chuck 423 in the X and Y directions and the θZ direction.

The die observation camera 421 (second camera) is arranged on the side of the wafer chuck 423 in the -Y direction (a second direction opposite to the first direction), and captures the target bonding surface of the die 51 held by the bonding head 432. The die observation camera 421 is used to obtain (measure) the surface state and/or the position of a pattern on the target bonding surface 51a of the die 51. For example, using a known image processing technique, the controller CNT detects the position of a feature point of the pattern on the target bonding surface 51a of the die 51 from an image obtained by capturing the target bonding surface 51a of the die 51 by the die observation camera 421. Thus, the controller CNT can measure the position of the pattern in the X and Y directions and/or the θZ direction on the target bonding surface 51a of the die 51.

The controller CNT is formed from, for example, a computer (information processing apparatus) including a processor such as a Central Processing Unit (CPU) and a storage unit such as a memory, and controls each unit of the bonding apparatus 100A. The controller CNT according to this embodiment controls, for example, a supply process and a bonding process. The supply process is a process of picking up, by the pickup head 31, one die 51 from the sheet 5a on which the plurality of dies 51 are arranged and supplying it to the bonding head 432. The bonding process is a process of bonding the die 51 to one (target region) of the plurality of bonding regions on the target bonding surface 6a of the wafer 6 by relatively driving the bonding head 432 and the wafer chuck 423 in the Z direction.

Furthermore, the controller CNT may perform, between the supply process and the bonding process, a process (alignment process) of aligning the wafer 6 (target region) and the die 51 by relatively driving the bonding head 432 and the wafer chuck 423 in the X and Y directions. More specifically, the controller CNT obtains the position of the pattern provided on the target bonding surface of the die 51 based on an image obtained by the die observation camera 421 by moving the stage 43 so as to arrange the die 51 on the bonding head 432 within the visual field of the die observation camera 421. Then, the controller CNT obtains the position of the pattern provided in the target region of the wafer 6 based on an image obtained by the wafer observation camera 431 by moving the stage 43 so as to arrange the target region of the wafer 6 within the visual field of the wafer observation camera 431. Based on these pieces of position information, the controller CNT can align the die 51 and the target region of the wafer 6.

In the bonding apparatus 100A according to this embodiment, the wafer chuck 423 is fixed to the upper base 42. Therefore, the bonding head 432 and the wafer chuck 423 are relatively driven by driving the stage 43 (or the bonding head 432) by the driving mechanism 43a. This embodiment has explained an example of the configuration of the bonding apparatus 100A provided with one pickup unit 3, one pickup head 31, one release head 32, and one bonding head 432. However, the bonding apparatus 100A may be provided with a plurality of pickup units 3, a plurality of pickup heads 31, a plurality of release heads 32, and a plurality of bonding heads 432.

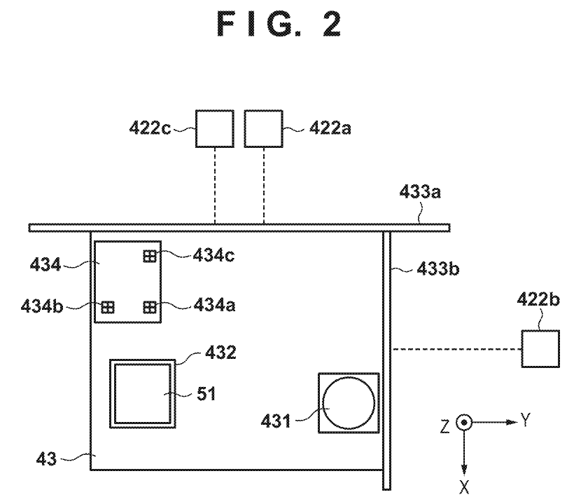

A detailed example of the configuration of the stage 43 will be described next. FIG. 2 is a view showing the stage 43 viewed from the +Z direction. A bar mirror 433a for performing position measurement in the X direction and the θZ direction (rotational direction), and a bar mirror 433b for performing position measurement in the Y direction are provided in the side portions of the stage 43. The bar mirror 433a is the target of interferometers 422a and 422c that perform position measurement in the X direction. The interferometers 422a and 422c are arranged apart in the Y direction. The rotational amount (θZ direction) of the stage 43 can be obtained from the difference between the measurement result of the interferometer 422a and that of the interferometer 422c. The bar mirror 433b is the target of an interferometer 422b that performs position measurement in the Y direction. The interferometers 422a to 422cmeasure in real time the position of the stage 43 in the X direction, the position in the Y direction, and the rotational amount in the θZ direction. The controller CNT can perform feedback control of driving of the stage 43 in real time and two-dimensionally position the stage 43 accurately. In the bonding apparatus 100A according to this embodiment, accurate position measurement by the interferometers 422a to 422c, and feedback control of the driving mechanism of the stage 43 based on the result of the position measurement can function as the positioning mechanism of the stage 43.

A reference plate 434 is provided on the upper surface of the stage 43 in addition to the wafer observation camera 431 and the bonding head 432 that holds the die 51. The reference plate 434 is made of a material with a low thermal expansion coefficient, and includes a plurality of marks 434a to 434c formed (drawn) with high positional accuracy. For example, as the reference plate 434, a plate formed by drawing marks on a quartz substrate using the drawing method of a semiconductor lithography process can be used. The marks 434a to 434c of the reference plate 434 can be captured (observed) by the die observation camera 421, but the present disclosure is not limited to this when a reference plate observation camera is separately provided. The stage 43 may be constituted by a coarse motion stage that can be driven within a large range, and a fine motion stage that can accurately be driven within a small range on the coarse motion stage. In this case, the wafer observation camera 431, the bonding head 432, the mirrors 433a and 433b, and the reference plate 434 can be provided on the fine motion stage.

A method of guaranteeing the origin position, magnification, the X-axis and Y-axis directions (rotation), and the orthogonality of the stage 43 using the reference plate 434 will be described. While controlling the die observation camera 421 to observe the mark 434a, the controller CNT obtains the measured values of the interferometers 422a to 422c when the mark 434a is arranged at the center of the image obtained by the die observation camera 421, and sets the obtained measured values as the origin of the stage 43. Then, while controlling the die observation camera 421 to observe the mark 434b, the controller CNT obtains the measured values of the interferometers 422a to 422c when the mark 434b is arranged at the center of the image obtained by the die observation camera 421. Based on the obtained measured values, the controller CNT decides the Y-axis direction and Y magnification of the stage 43. Next, while controlling the die observation camera 421 to observe the mark 434c, the controller CNT obtains the measured values of the interferometers 422a to 422c when the mark 434c is arranged at the center of the image obtained by the die observation camera 421. Based on the obtained measured values, the controller CNT decides the X-axis direction and X magnification of the stage 43.

Thus, a direction from the mark 434b toward the mark 434a on the reference plate 434 is defined as the Y-axis of the bonding apparatus 100A, a direction from the mark 434c toward the mark 434a is defined as the X-axis of the bonding apparatus 100A, and the directions and orthogonality of the axes are calibrated. In addition, the interval between the mark 434b and the mark 434a is defined as the scale reference of the bonding apparatus 100A in the Y direction, the interval between the mark 434c and the mark 434a is defined as the scale reference of the bonding apparatus 100A in the X direction, and calibration is performed. The refractive index of the optical path of the interferometer changes due to variations of the atmospheric pressure and temperature, this makes the measured value vary, and thus it is desirable for the interferometers 422a to 422c to perform calibration at an arbitrary timing and guarantee the origin position, magnification, rotation, and orthogonality of the stage 43. Note that to reduce variations of the measured values of the interferometers 422a to 422c, the space in which the stage 43 moves may be covered with a temperature control chamber to control the temperature.

In this embodiment, an example in which the reference plate 434 is arranged on the stage 43 and the reference plate 434 is observed by the die observation camera 421 has been described, but the present disclosure is not limited to this. For example, the reference plate 434 may be arranged on the upper base 42 to observe the reference plate 434 by the wafer observation camera 431. Even in this configuration, the origin position, magnification, rotation, and orthogonality of the stage 43 can be guaranteed. In this embodiment, an example in which calibration is performed by observing the reference plate 434 has been described, but the present disclosure is not limited to this. For example, calibration may be performed by an abutting operation to a reference surface. Alternatively, accurate positioning of the stage 43 may be performed using a position measurement means such as a white interferometer for which an absolute value is guaranteed.

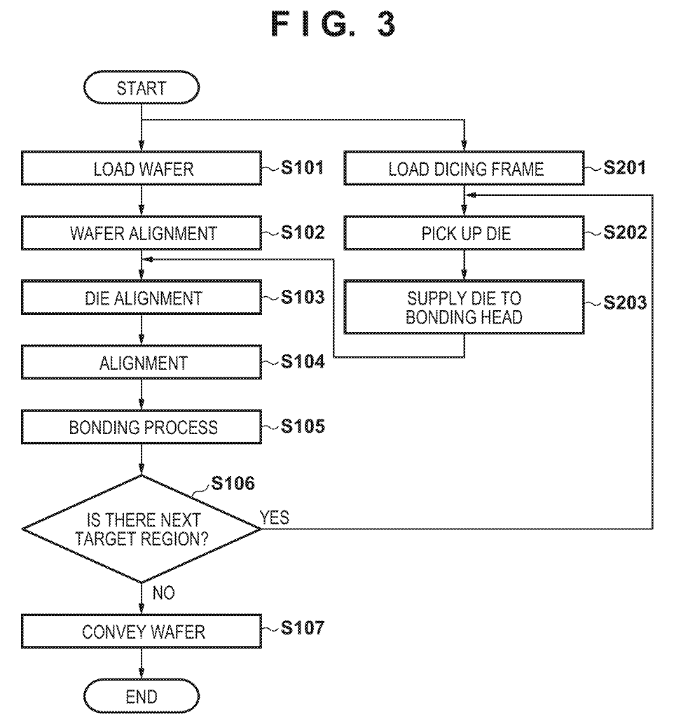

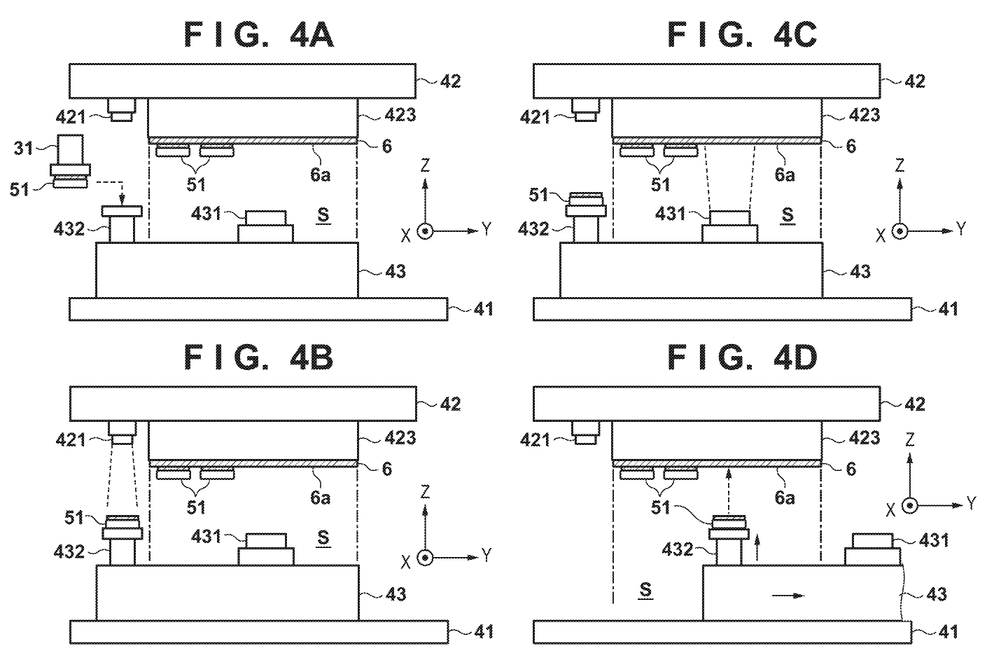

The operation of the bonding apparatus 100A according to this embodiment will be described next with reference to FIGS. 3 and 4A to 4D. FIG. 3 is a flowchart illustrating the operation procedure of the bonding apparatus 100A according to this embodiment. The controller CNT can execute processes in the flowchart of FIG. 3. FIGS. 4A to 4D are views for explaining the operation of the bonding apparatus 100A according to this embodiment and show only the bonding unit 4.

In step S101, the controller CNT loads the wafer 6 serving as the first member onto the wafer chuck 423 of the bonding apparatus 100A using a wafer conveyance mechanism (not shown). As described above, the wafer chuck 423 according to this embodiment holds the wafer 6 in a state in which the target bonding surface 6a of the wafer 6 faces down so as to reduce adhesion (accumulation) of foreign particles to the target bonding surface 6a of the wafer 6. Therefore, the wafer conveyance mechanism turns over the wafer 6 extracted from a storage container such as a Front Opening Unify Pod (FOUP), and conveys the wafer 6 to the wafer chuck 423 in the state in which the target bonding surface 6a of the wafer 6 faces down. In this case, the operation of turning over the direction of the wafer 6 to make the target bonding surface 6a of the wafer 6 face down is preferably performed immediately after the wafer 6 is extracted from the storage container. This can reduce adhesion of foreign particles to the target bonding surface 6a of the wafer 6 during conveyance of the wafer 6 from the storage container to the wafer chuck 423.

At this time, the space in the bonding apparatus 100A is desirably kept at a high cleanliness of about class 1. To keep a high cleanliness for the wafer 6, the storage container desirably has a high airtightness and maintains a high cleanliness. After positions of the wafer 6 in the θZ direction and the X and Y directions are measured by a prealignment unit (not shown) and the wafer 6 is coarsely positioned based on the measurement result, the wafer 6 may be conveyed onto the wafer chuck 423. The position of the wafer 6 in the θZ direction can be measured by detecting a notch or orientation flat of the wafer 6, and the position of the wafer 6 in the X and Y directions can be measured by detecting the outer shape of the wafer 6.

In the bonding apparatus 100A according to this embodiment, to increase the cleanliness of the wafer 6, a washing mechanism that washes the wafer 6 may be provided in the bonding apparatus 100A. A mechanism that performs a preprocess for the bonding process on the wafer 6 may also be provided in the bonding apparatus 100A. For example, the preprocess is a process of applying an adhesive to the target bonding surface 6a of the wafer 6 in bonding using an adhesive, or a process of activating the target bonding surface 6a of the wafer 6 in hybrid bonding.

In step S102, the controller CNT performs wafer alignment using the wafer observation camera 431. In the wafer alignment, the wafer observation camera 431 captures the target bonding surface 6a of the wafer 6, and the position (for example, in the X and Y directions, the Z direction, and the θZ direction) of the wafer 6 held by the wafer chuck 423 is obtained based on a thus obtained image.

Focus adjustment when capturing the target bonding surface 6a of the wafer 6 may be performed by the focus adjustment mechanism of the wafer observation camera 431, or by driving the wafer 6 in the Z direction by the Z driving mechanism of the wafer chuck 423. When an alignment mark is provided on the target bonding surface 6a of the wafer 6, the position of the wafer 6 can be obtained using the alignment mark. To the contrary, when no alignment mark is provided on the target bonding surface 6a of the wafer 6, the position of the wafer 6 may be obtained using a portion (feature point) of the pattern provided on the target bonding surface 6a.

For example, the controller CNT can obtain the position of the wafer 6 by measuring the image position of a projected alignment mark or a part (feature point) of the pattern with respect to the center of the image obtained by the wafer observation camera 431. The alignment mark or the part (feature point) of the pattern will sometimes be referred to as an alignment mark or the like hereinafter. As an example, there is a method of measuring the position of the alignment mark or the like with respect to the reference point of the bonding apparatus 100A. According to this method, the stage 43 is driven in advance to make a mark formed on the reference plate 434 fall within the visual field of the die observation camera 421, and the die observation camera 421 captures the mark on the reference plate 434. Based on the position of the stage 43 at that time and the mark position within the image obtained by the die observation camera 421, the reference point of the bonding apparatus 100A is decided. Based on the image obtained by capturing the alignment mark or the like by the wafer observation camera 431, the offset amount of the alignment mark or the like with respect to the reference point is obtained. The position of the wafer 6 with respect to the reference point can be measured accurately based on the obtained position of the reference point and the obtained offset amount. Note that as the position of the reference point of the bonding apparatus 100A, the position of the mark on the reference plate 434 is used. However, the position of another place may be used as long as it is a position serving as a reference.

If the rotation amount of the wafer 6 held by the wafer chuck 423 in the θZ direction is large, the wafer 6 is desirably resupplied onto the wafer chuck 423 so as to reduce (correct) the rotation amount of the wafer 6 in the θZ direction. When the wafer 6 is resupplied onto the wafer chuck 423, the position of the wafer 6 needs to be measured again. During execution of step S102, the surface position of the target bonding surface 6a of the wafer 6 may be measured using a height measurement means (not shown) that measures the surface position (height) of the target bonding surface 6a of the wafer 6. This is because the thickness of the wafer 6 varies, and the surface position of the target bonding surface 6a of the wafer 6 is important to accurately manage (control) the gap between the wafer 6 and the die 51 in the bonding process.

The origin position, the magnification, the position in the X and Y directions, rotation in the θZ direction, and the orthogonality are guaranteed for the stage 43 using the reference plate 434. For this reason, the position of the wafer 6 held by the wafer chuck 423 can be measured with respect to the origin position of the stage 43 and the like. On the target bonding surface 6a of the wafer 6, a plurality of regions each including a semiconductor device to which the die 51 is to be electrically connected are repetitively arranged, as a plurality of bonding regions that should bond the dies 51, at a predetermined period in the wafer 6. Since the semiconductor device in each bonding region is accurately positioned and manufactured using a semiconductor manufacturing apparatus, the plurality of bonding regions on the target bonding surface 6a of the wafer 6 are accurately arrayed generally at a repetitive period with a nano-level accuracy. Hence, in the wafer alignment of step S102, it is not necessary to measure the positions of all regions on the target bonding surface 6a of the wafer 6, and it is only necessary to measure the positions of some of the plurality of bonding regions on the target bonding surface 6a of the wafer 6. More specifically, the positions of semiconductor devices (patterns or marks) in three or more bonding regions among the plurality of bonding regions on the target bonding surface 6a of the wafer 6 are measured, and a statistical process is performed. Accordingly, the array of bonding regions on the target bonding surface 6a of the wafer 6, the origin position of the array, the position in the X and Y directions, the rotation amount in the θZ direction, the orthogonality, and the magnification error of the repetitive period can be calculated.

The wafer chuck 423 may include a mechanism that controls the temperature of the wafer 6. This is because, for example, in a case where the thermal expansion coefficient of a silicon wafer is 3 ppm/°C, and the diameter of the wafer is 300 mm, if the temperature increases by 1°C, the position of the outermost periphery moves by 150 mm × 0.000003 = 0.00045 mm = 450 nm. If a bonding position (for example, the position of the target region) moves after wafer alignment, it may be difficult to accurately bond the wafer 6 and the die 51. Thus, the temperature of the wafer 6 is preferably controlled to keep the temperature change of the wafer 6 to be 0.1°C or less.

Note that in this embodiment, the wafer 6 is used as the first member. If an interposer on which wirings are formed is used as the first member, not the array of semiconductor devices but the array of the repetitively formed wirings is measured. If a wafer or panel without a pattern is used as the first member, wafer alignment in step S102 need not be executed.

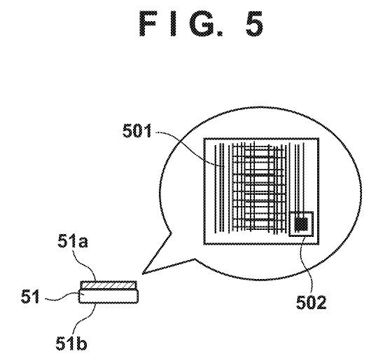

Steps S101 and S102 described above are processes regarding the wafer 6 serving as the first member. On the other hand, in parallel to steps S101 and S102, processes (steps S201 to S203) regarding the die 51 serving as the second member are executed. FIG. 5 is a schematic view showing an example of the configuration of the die 51. The die 51 has the target bonding surface 51a and a back surface 51b that is a surface opposite to the target bonding surface 51a. The target bonding surface 51a of the die 51 includes an element pattern 501 and an alignment mark 502. It may be understood that the element pattern 501 includes electrodes (bumps) to be electrically connected to electrodes provided on the wafer 6.

In step S201, the controller CNT loads the dicing frame 5 to the pickup unit 3 (onto the frame holder 33) using a conveyance mechanism (not shown). The dicing frame 5 is a frame having an opening at the center, and the sheet 5a (for example, a dicing tape) is adhered to the dicing frame 5 so as to cover the opening. The plurality of dies 51 divided by a cutter such as a dicer are arrayed on the sheet 5a. Conventionally, the dicing frame 5 is conveyed by an unsealed magazine. However, adhesion of foreign particles to the target bonding surface of the die 51 causes a bonding failure, so the dicing frame 5 needs to be conveyed in a container that has a high airtightness and maintains a high cleanliness. Here, to increase the cleanliness of the die 51, a washing mechanism that washes the die 51 on the dicing frame 5 (sheet 5a) may be provided inside the bonding apparatus 100A. After the rotation of the dicing frame 5 in the θZ direction and the shift position (position in the X and Y directions) of the dicing frame 5 are coarsely determined by a prealignment unit (not shown) based on the outer shape of the dicing frame 5, the dicing frame 5 can be conveyed onto the frame holder 33.

In step S202, the controller CNT controls the pickup head 31 and the release head 32 to pick up one die 51 from the dicing frame 5 (sheet 5a). More specifically, the controller CNT moves the pickup head 31 and the release head 32 to the position of the die 51 to be picked up (to be also referred to as the target die 51 hereinafter). The controller CNT drives the release head 32 in the +Z direction to push up the target die 51 from the back side of the sheet 5a. In this state, the controller CNT drives the pickup head 31 in the -Z direction to bring the pickup head 31 and the target die 51 into contact with each other. The target die 51 is then held (sucked) by the pickup head 31 by a vacuum suction force or the like, and can be peeled from the sheet 5a by driving the pickup head 31 in the +Z direction. The target die 51 to be picked up can be decided based on Known Good Die (KGD) information transmitted to the bonding apparatus 100A online. Normally, only a known good die is picked up as the target die 51. However, as the target die 51 to be bonded to the bonding region including a defective device among the plurality of bonding regions on the target bonding surface 6a of the wafer 6, a known bad die (KBD) may be picked up.

In step S203, the controller CNT performs a supply process of supplying the target die 51 picked up by the pickup head 31 to the bonding head 432 of the bonding unit 4. More specifically, the controller CNT arranges the pickup head 31 above the bonding head 432 by moving, in the X direction, the pickup head 31 picking up the target die 51. The controller CNT then supplies (delivers) the target die 51 from the pickup head 31 to the bonding head 432 by driving the pickup head 31 in the -Z direction.

As shown in FIG. 4A, the supply process is performed in a state in which the bonding head 432 is arranged outside a space S (to be sometimes referred to as a lower space S hereinafter) below the wafer 6 held by the wafer chuck 423. That is, when performing the supply process, the stage 43 moves so as to arrange the bonding head 432 outside the lower space S. By performing the supply process in a state in which the bonding head 432 is arranged outside the lower space S, as described above, it is possible to reduce adhesion of foreign particles to the target bonding surface 6a of the wafer 6 caused by supplying the die 51 from the pickup head 31 to the bonding head 432.

In this embodiment, when picking up the target die 51 by the pickup head 31, the target bonding surface 51a of the target die 51 faces up (in +Z direction) and is held by (in contact with) the pickup head 31. In contrast, when delivering the target die 51 from the pickup head 31 to the bonding head 432, the target bonding surface 51a of the target die 51 faces up and the back surface on the opposite side of the target bonding surface 51a of the target die 51 is held by the bonding head 432. That is, each of the pickup head 31 and the bonding head 432 according to this embodiment is configured to hold the die 51 in a state in which the target bonding surface 51a of the die 51 faces up. Therefore, the pickup head 31 supplies the picked-up target die 51 to the bonding head 432 without flip-chipping (turning over) the target die 51.

In this embodiment, an example in which the pickup head 31 directly conveys the target die 51 to the bonding head 432 has been described, but the present disclosure is not limited to this. For example, when one or more conveyance mechanisms are provided on the conveyance path of the target die 51 to the bonding head 432, the target die 51 may be conveyed to the bonding head 432 through a process of delivering the target die 51 to the one or more conveyance mechanisms. A mechanism that performs a preprocess for the bonding process on the target die 51 may be provided inside the bonding apparatus 100A. The preprocess is, for example, a process of applying an adhesive to the target bonding surface 51a of the target die 51 in bonding using an adhesive, or a process of activating the target bonding surface 51a of the target die 51 in hybrid bonding. As the preprocess, a washing process of the target die 51 may be executed. The preprocess may be performed while conveying the target die 51 to the bonding head 432.

By the above processes, the wafer 6 is held by the wafer chuck 423, and the target die 51 is held by the bonding head 432. That is, the bonding process of bonding the target die 51 to the target region of the wafer 6 can be executed.

In step S103, the controller CNT performs die alignment using the die observation camera 421. The die observation camera 421 is arranged to capture the target bonding surface 51a of the target die 51 on the bonding head 432 while the bonding head 432 is arranged outside the lower space S. In the die alignment, as shown in FIG. 4B, the stage 43 is moved so as to arrange the target bonding surface 51a of the target die 51 on the bonding head 432 within the visual field of the die observation camera 421. Then, the die observation camera 421 captures the target bonding surface 51a of the target die 51, and the position of the pattern provided on the target bonding surface 51a of the target die 51 is obtained based on a thus obtained image.

Focus adjustment when capturing the target bonding surface of the target die 51 may be performed by the focus adjustment mechanism of the die observation camera 421, or by driving the bonding head 432 in the Z direction by the driving mechanism 43a of the stage 43. When the Z driving mechanism for driving the die observation camera 421 in the Z direction is provided, focus adjustment may be performed using the Z driving mechanism. In this embodiment, as shown in FIG. 5, the alignment mark 502 is provided on the target bonding surface 51a of the target die 51, so the position of the pattern 501 of the target die 51 can be obtained using the alignment mark 502. On the other hand, for a general die, an alignment mark is often arranged on a scribe line and removed together with the scribe line. In this case, the position of the pattern of the target die 51 may be obtained using a feature point that allows specification of the position of the pattern. As the feature point, for example, the end of the array of pads or bumps arranged on the target bonding surface of the target die 51, a region having an aperiodic array, the outer edge (outer shape) of the die, or the like can be used.

For example, the controller CNT can measure the position of the pattern of the target die 51 by measuring the image position of the projected alignment mark or feature point with respect to the center of the image obtained by the die observation camera 421. The measurement of the position of the target die 51 can include measurement of the rotation amount (rotation in the θZ direction) of the target die 51. The rotation amount of the target die 51 can be measured by, for example, obtaining the positions of a plurality of feature points on the target bonding surface 51a of the target die 51 based on the image obtained by the die observation camera 421. The positions of the plurality of feature points can be obtained based on a plurality of images obtained by individually capturing the feature points while driving the bonding head 432 by the stage 43. Alternatively, when the entire target die 51 falls within the visual field of the die observation camera 421, the positions of the plurality of feature points can be obtained from an image obtained by capturing the entire target bonding surface 51a of the target die 51 by the die observation camera 421. The rotation amount of the target die 51 can be corrected by rotating the bonding head 432 by the stage 43 in the bonding process. However, the measurement range of the interferometer 422 in the rotational direction is narrow. Thus, if the rotation amount of the target die 51 is large, the target die 51 is desirably rearranged on the bonding head 432 so as to correct the rotation amount of the target die 51. When the target die 51 is rearranged on the bonding head 432, the position of the target die 51 needs to be measured again.

During execution of step S103, the surface position of the target bonding surface 51a of the target die 51 is preferably measured using a height measurement means (not shown) that measures the surface position (height) of the target bonding surface 51a of the target die 51. Since the thickness of the target die 51 varies, the surface position of the target bonding surface 51a of the target die 51 is important to accurately manage (control) the gap between the wafer 6 and the target die 51 in the bonding process. Furthermore, the heights of a plurality of positions on the target bonding surface 51a of the target die 51 (that is, the height distribution of the target bonding surface 51a of the target die 51) may be measured to adjust the relative postures (tilts) of the wafer 6 and the target die 51 based on the measurement result in the bonding process. The relative postures can be adjusted by a tilt mechanism mounted on the wafer chuck 423 and/or the stage 43.

Information representing the correspondence between the measured positions of the feature points of the die 51 and the outer shape of the die 51 is preferably generated. The correspondence indicates the positional relationship between the outer shape of the die 51 and the element pattern 501 or the alignment mark 502 on the target bonding surface 51a. The information representing the correspondence is stored in a storage device (not shown) inside or outside the apparatus. In step S103, the correspondence between the positions of the feature points of the die 51 and the outer shape of the die 51 is obtained by measuring the element pattern 501 or the alignment mark 502 as the feature point of the die 51 on the target bonding surface 51a, and the whole or a part of the outer shape of the die 51. However, the present disclosure is not limited to this, and the information representing the correspondence may be generated by an external apparatus and input to the bonding apparatus 100A.

In step S103, the quality of the target bonding surface 51a of the target die 51 is desirably measured. The quality can include the good condition of the target die 51, the foreign particle adhesion state of the target bonding surface 51a of the target die 51, and the activated state of the target bonding surface 51a of the target die 51. For example, in hybrid bonding, if foreign particles adhere to the target bonding surface 51a during conveyance of the target die 51, this influences the bonding strength of the target die 51, and the quality of die immediately before the bonding process is thus important. The controller CNT determines the quality of the target die 51 based on an image obtained by observing, by the die observation camera 421, the outer shape of the target die 51 and the target bonding surface 51a (element pattern 501). The controller CNT may determine the quality of the target die 51 by obtaining in advance the information of the die 51 on the dicing frame 5 by the pickup unit 3, and comparing the obtained information with the information of the die 51 obtained on the bonding head 432.

In step S104, the controller CNT drives the stage 43 to perform alignment between the wafer 6 and the target die 51 so that the pattern of the target region of the wafer 6 and the pattern of the target die 51 overlap each other. As described above, the target region of the wafer 6 is a target bonding region to which the target die 51 on the bonding head 432 is bonded, among the plurality of bonding regions on the target bonding surface 6a of the wafer 6. For example, as shown in FIG. 4C, the controller CNT moves the stage 43 to make the target region of the wafer 6 fall within the visual field of the wafer observation camera 431. Then, the wafer observation camera 431 captures the target region of the wafer 6, and the position of the pattern provided in the target region of the wafer 6 is obtained based on a thus obtained image. This allows the controller CNT to perform alignment between the target region of the wafer 6 and the target die 51 based on the position of the pattern of the target die 51 obtained in step S103 and the position of the pattern of the target region of the wafer 6 obtained in step S104. At this time, alignment between the wafer 6 and the target die 51 is preferably performed so as to reduce a relative rotation deviation and/or a posture deviation between the wafer 6 and the target die 51. If the relative position between the wafer 6 and the target die 51 is predicted to change (shift) when bonding the wafer 6 and the target die 51, the wafer 6 and the target die 51 may be aligned using the change of the relative position as an offset amount. The offset amount can be obtained in advance by experiment, simulation, or the like. Note that if the position of the pattern of the target region of the wafer 6 is obtained in the wafer alignment in step S102, the process of capturing the target region of the wafer 6 by the wafer observation camera 431 and obtaining the position of the pattern of the target region may be omitted in step S104.

In step S105, the controller CNT bonds the target die 51 to the target region of the wafer 6 by narrowing the interval between the wafer 6 and the target die 51 (bonding process). The bonding process may be performed by driving the bonding head 432 (target die 51) in the Z direction, or driving the wafer chuck 423 (wafer 6) in the Z direction. Alternatively, the bonding process may be performed by driving the bonding head 432 (target die 51) and the wafer chuck 423 (wafer 6) relatively in the Z direction. To accurately control the interval between the wafer 6 and the target die 51, it is preferable to provide a detector (for example, an encoder) that detects the position of the bonding head 432 and/or wafer chuck 423 in the Z direction, and perform feedback control based on the detection result of the detector. At this time, the bonding process is performed in a state in which the bonding head 432 is arranged inside the lower space S, as shown in FIG. 4D. That is, when performing the bonding process, the stage 43 moves so as to arrange the bonding head 432 inside the lower space S.

To improve the alignment accuracy of the wafer 6 and the target die 51 even during execution of the bonding process, the relative position between the wafer 6 and the target die 51 in the X and Y directions can be controlled. In this case, the width of the mirror 433 in the Z direction is preferably so set as to irradiate the mirror 433 with light from the interferometer 422 even if the stage 43 is driven in the Z direction. Furthermore, a detector (for example, an encoder or a gap sensor) that detects the relative position between the wafer chuck 423 and the stage 43 in the X and Y directions may be provided. In this case, feedback control of the relative position can be performed while the detector detects (monitors) the relative position between the wafer chuck 423 and the stage 43 in the X and Y directions during execution of the bonding process. Note that if the wafer 6 and the target die 51 come into contact with each other, the position of the stage 43 feedback-controlled based on the measurement result of the interferometer 422 is restrained. Hence, the control method of the relative position between the wafer 6 and the target die 51 in the X and Y directions is preferably switched before and after contact by, for example, stopping the feedback process at the start of contact between the wafer 6 and the target die 51.

In bump bonding, a process necessary for the bump bonding may be executed in step S105 by, for example, pressing the target die 51 against the wafer 6 at a predetermined pressure (pressing pressure). In hybrid bonding, a process of applying an impact serving as a trigger for the start of bonding may be executed in step S105. A process of observing the bonding state (bonding deviation amount) between the wafer 6 and the target die 51 after bonding may also be executed in step S105.

In step S106, the controller CNT judges whether the dies 51 are bonded to all the plurality of bonding regions on the target bonding surface 6a of the wafer 6. Normally, several tens to several hundreds of semiconductor devices are formed as a plurality of bonding regions on one wafer 6, and the die 51 can be bonded to each of the plurality of bonding regions. If a bonding region (next target region) to which the die 51 is to be bonded next exists on the wafer 6, the process returns to step S202. That is, the supply process and the bonding process are alternately performed for one wafer 6. On the other hand, if no next target region exists on the wafer 6, that is, the dies 51 are bonded to all the plurality of bonding regions on the target bonding surface 6a of the wafer 6, the process advances to step S107.

In this embodiment, an example in which whether the next target region exists is judged after the end of the bonding process, and the process returns to step S202 has been explained. However, the judgment of whether the next target region exists may be performed before the end of the bonding process. In this case, step S202 can be performed in parallel to execution of the bonding process. That is, in parallel to execution of the bonding process, the die 51 to be bonded to the next target region is picked up from the dicing frame 5 (sheet 5a). At this time, by providing a plurality of bonding heads 432 and/or a plurality of pickup heads 31, the parallel process can be performed more quickly. In a case where a plurality of types of dies 51 are bonded to each bonding region (semiconductor device) on the wafer 6, dies of one type are bonded to all the bonding regions of the wafer 6 and then bonding of dies of the next type starts. At the start of bonding dies of the next type, the loading operation (step S201) of the dicing frame 5 on which dies of the next type are arranged is executed and then the die pickup in step S202 can be executed.

In step S107, using the wafer conveyance mechanism (not shown), the controller CNT unloads, from the wafer chuck 423, the wafer 6 on which the dies 51 are bonded to each of the plurality of bonding regions. There can be considered a case where the wafer 6 is returned to the container (for example, the FOUP) used for the loading of the wafer 6 and a case where the wafer 6 is returned to a container different from that container. The wafer 6 is preferably returned to another container because the thickness of the whole wafer 6 to which the dies 51 are bonded changes and the gap between the wafers 6 needs to be increased, as compared with the wafers 6 before the bonding process. The operation procedure of the bonding apparatus 100A for bonding the dies 51 to each of the plurality of bonding regions on one wafer 6 has been described above. However, when bonding the dies 51 to each of a plurality of wafers 6, the flowchart of FIG. 3 is repeated.

Note that since the number of dies 51 on the dicing frame 5 and the number of the plurality of bonding regions on the wafer 6 are generally different, loading of the wafer 6 and loading of the dicing frame 5 do not synchronize in most cases. If the dies 51 on the dicing frame 5 run out during bonding of the dies 51 to one wafer 6, the next dicing frame 5 can be loaded into the bonding apparatus 100A. On the other hand, if the dies 51 remain on the dicing frame 5 even after the end of bonding the dies 51 to one wafer 6, the remaining dies 51 can be used for the next wafer 6.

As described above, in the bonding apparatus 100A according to this embodiment, the wafer chuck 423 is configured to hold the wafer 6 in a state in which the target bonding surface 6a of the wafer 6 faces down. The bonding head 432 is arranged outside the lower space S in the supply process, and is arranged inside the lower space S in the bonding process. With this configuration, it is possible to reduce the occurrence of a bonding failure between the wafer 6 and the dies 51 caused by adhesion (accumulation) of foreign particles to the target bonding surface 6a of the wafer 6.

### Second Embodiment

The second embodiment according to the present disclosure will be described. In the case of a wafer chuck 423 that holds a wafer 6 in a state in which a target bonding surface 6a of the wafer 6 faces down, the wafer 6 may drop from the wafer chuck 423 at the time of abnormality. To cope with this, a bonding apparatus 100B according to this embodiment can further include a receiving member 441 for receiving the wafer 6 that has dropped from the wafer chuck 423. Note that this embodiment basically inherits the first embodiment and can comply with the first embodiment except matters mentioned below.

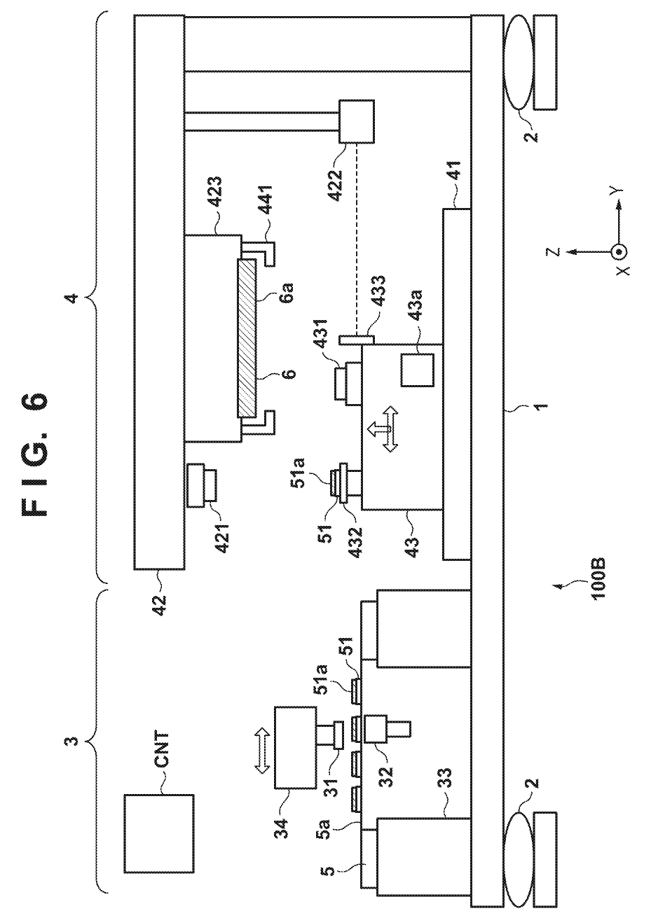

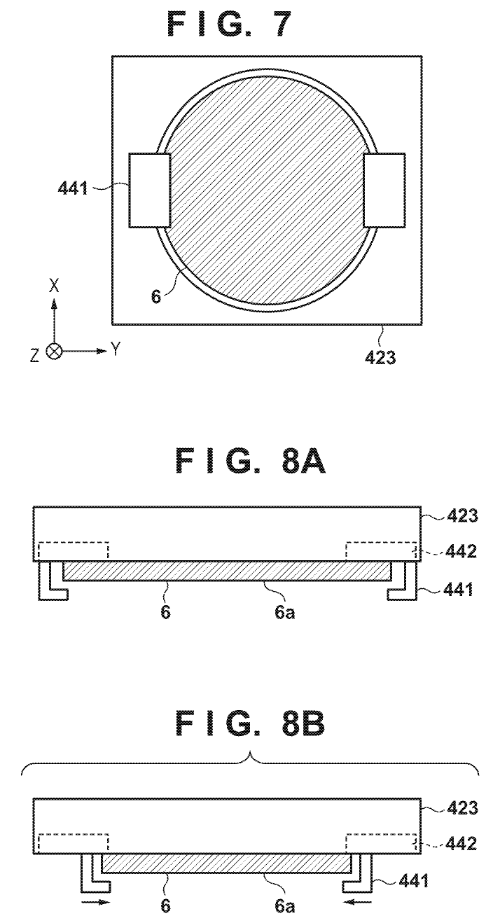

FIG. 6 is a schematic view showing an example of the configuration of the bonding apparatus 100B according to the second embodiment. The bonding apparatus 100B according to this embodiment basically has the same configuration as that of the bonding apparatus 100A according to the first embodiment but is different in that the receiving member 441 is provided in the wafer chuck 423. The receiving member 441 is a member for receiving the wafer 6 that has dropped from the wafer chuck 423. The receiving member 441 is arranged apart from the wafer 6 under at least a part of the outer peripheral portion (peripheral edge portion) of the wafer 6 held by the wafer chuck 423. As shown in FIG. 7, the receiving member 441 according to this embodiment is formed as a claw member that can receive the wafer 6 that has dropped from the wafer chuck 423 but the shape of the receiving member 441 is not limited to the claw shape. FIG. 7 is a view of the wafer chuck 423 according to this embodiment from below (the -Z direction side). The number of receiving members 441 is not limited to two, and may be one or three or more.

The receiving member 441 may be formed as a drop prevention member for preventing the wafer 6 from dropping from the wafer chuck 423. The receiving member 441 serving as the drop prevention member may be configured to contact at least a part of the outer peripheral portion (peripheral edge portion) of the wafer 6 held by the wafer chuck 423 and press at least the part against the wafer chuck 423.

As shown in FIGS. 8A and 8B, the bonding apparatus 100B according to this embodiment may further include a driving mechanism 442 that drives the receiving member 441 to be inserted/extracted from below the outer peripheral portion of the wafer 6 held by the wafer chuck 423. For example, the driving mechanism 442 can be configured to drive the receiving member 441 in the X and Y directions. This can adjust the position of the receiving member 441 in the X and Y directions in accordance with the size of the wafer 6 held by the wafer chuck 423. Furthermore, by retracting the receiving members 441 when loading the wafer 6 onto the wafer chuck 423 or unloading the wafer 6 from the wafer chuck 423, it is possible to avoid the wafer conveyance mechanism contacting the receiving members 441.

### Embodiment of Article Manufacturing Method

A method of manufacturing an article (a semiconductor IC element, a liquid crystal display element, a MEMS, or the like) using the above-described bonding apparatus will be described. The article manufacturing method according to the embodiment of the present disclosure is suitable for manufacturing an article, for example, a microdevice such as a semiconductor device or an element having a fine structure. The article manufacturing method according to this embodiment includes a step of bonding a second member to each of a plurality of regions on a target bonding surface of a first member using the above-described bonding apparatus, a step of processing the first member on which the second member is bonded to each of the plurality of regions, and a step of manufacturing an article from the processed first member. The first member is, for example, a wafer (substrate), and the second member is, for example, a die. The manufacturing method also includes other known steps (probing, dicing, bonding, packaging, and the like). The article manufacturing method according to this embodiment is advantageous in at least one of the performance, quality, productivity, and production cost of the article, as compared to conventional methods.

### Other Embodiments

Embodiments of the present disclosure can also be realized by a computer of a system or apparatus that reads out and executes computer executable instructions (e.g., one or more programs) recorded on a storage medium (which may also be referred to more fully as a 'non-transitory computer-readable storage medium') to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2025-006262, filed on January 16, 2025, which is hereby incorporated by reference herein in its entirety.

What is claimed is:

1. A bonding apparatus for bonding a second member to each of a plurality of regions on a target bonding surface of a first member, comprising:
a first holder configured to hold the first member in a state in which the target bonding surface faces down; and
a second holder configured to hold the second member,
wherein in a supply process of supplying the second member to the second holder, the second holder is arranged outside a space below the first member held by the first holder, and
wherein in a bonding process of bonding, to one of the plurality of regions, the second member supplied to the second holder, the second holder is arranged inside the space.

2. The apparatus according to claim 1, further comprising a stage on which the second holder is provided,
wherein the stage moves so as to arrange the second holder outside the space in the supply process, and moves so as to arrange the second holder inside the space in the bonding process.

3. The apparatus according to claim 2, further comprising a first camera configured to capture the target bonding surface of the first member held by the first holder,
wherein the first camera is provided on the stage.

4. The apparatus according to claim 3, wherein before the bonding process, the stage moves so that the first camera captures a target region, to which the second member supplied to the second holder by the supply process is bonded, among the plurality of regions.

5. The apparatus according to claim 1, further comprising a second camera configured to capture the second member supplied to the second holder by the supply process, in a state in which the second holder is arranged outside the space.

6. The apparatus according to claim 5, further comprising a fixing member to which the first holder is fixed,
wherein the second camera is provided in the fixing member.

7. The apparatus according to claim 6, further comprising a stage on which the second holder is provided, and a first camera configured to capture the target bonding surface of the first member held by the first holder,
wherein the first camera is provided on the stage to be arranged on a side of the second holder in a first direction, and
the second camera is provided in the fixing member to be arranged on a side of the first holder in a second direction opposite to the first direction.

8. The apparatus according to claim 1, further comprising a receiving member configured to receive the first member that has dropped from the first holder,
wherein the receiving member is arranged apart from the first member under at least a part of an outer peripheral portion of the first member held by the first holder.

9. The apparatus according to claim 8, further comprising a driving mechanism configured to drive the receiving member to be inserted/extracted from below the outer peripheral portion of the first member held by the first holder.

10. The apparatus according to claim 1, further comprising a supply head configured to pick up one second member from a sheet on which a plurality of second members are arranged, and supply the second member to the second holder.

11. The apparatus according to claim 10, wherein the supply head supplies the picked-up second member to the second holder without flip-chipping.

12. The apparatus according to claim 1, wherein the supply process and the bonding process are alternately performed.

13. The apparatus according to claim 1, wherein the first member is a substrate, and the second member is a die.

14. An article manufacturing method comprising:
bonding a second member to each of a plurality of regions on a target bonding surface of a first member using a bonding apparatus defined in claim 1;
processing the first member on which the second member is bonded to each of the plurality of regions; and
manufacturing an article from the processed first member.
